(19) United States
(12) Patent Application Publication
(10) Pub. No.: US 2019/0010602 A1
(43) Pub. Date: Jan. 10, 2019

(54) METHODS AND APPARATUSES TO CLAMP COVER SUBSTRATES IN A VACUUM COATING PROCESS WITH VAN DER WAALS FORCES

(71) Applicant: CORNING INCORPORATED, CORNING, NY (US)

(72) Inventors: Daniel Robert Boughton, Naples, NY (US); James Gerard Fagan, Painted Post, NY (US); Sumalee Likitvanichkul Fagan, Painted Post, NY (US)

(21) Appl. No.: 16/067,265

(22) PCT Filed: Dec. 29, 2016
(86) PCT No.: PCT/US2016/069077

§ 371 Date: Jun. 29, 2018

Related U.S. Application Data
(60) Provisional application No. 62/337,984, filed on May 18, 2016.
(60) Provisional application No. 62/272,947, filed on Dec. 30, 2015.

(51) Int. Cl. C23C 14/50; C23C 14/02; C23C 14/34

(52) U.S. Cl. CPC C23C 14/50; C23C 14/34; C23C 14/021

(57) ABSTRACT

A chucking apparatus and method for vacuum processing mobile device cover substrates in a vacuum chamber in which the chucking apparatus is configured for temporarily securing the cover substrate within the vacuum chamber, and includes a carrier substrate with a CTE within 20% of CTE of the cover substrate to prevent the carrier substrate and the cover substrate from becoming detached from one another due to differing rates of thermal expansion during processing in the vacuum chamber. The carrier substrate has a surface contact area in contact with the cover substrate selected to provide for continuous bonding during the processing in the vacuum chamber and to provide for de-bonding after the process in the vacuum chamber is complete. Further, the carrier substrate is prepared for use with a cleaning process that facilitates Van der Waals bonding between the carrier substrate and the cover substrate.

### CROSS-REFERENCE TO RELATED APPLICATIONS

This application claims the benefit of priority under 35 U.S.C. § 119 of U.S. Provisional Application Ser. No. 62/337,984 filed on May 18, 2016 and U.S. Provisional Application Ser. No. 62/272,947 filed on Dec. 30, 2015, the contents of each of which are relied upon and incorporated herein by reference in their entireties.

### BACKGROUND

The present disclosure relates to the general field of chucking or clamping a substantially two-dimensional (flat or 2D) cover substrate and/or a substantially three-dimensional (sometimes referred to as curved or 3D) cover substrate for the purpose of plasma processing, such as to allow vacuum (e.g., physical vapor deposition or chemical vapor deposition) by which coatings or treatments are applied to the substrate. Typically, such cover substrates are coated to receive anti-reflective or anti-scratch properties. In particular, the present disclosure relates to such chucking by means of Van der Waals bonding or “VdW” bonding for short.

Handheld display substrates (typically made from glass) with treatments is being developed to meet market demands, and such treatments include antimicrobial surface treatments and scratch resistant optical coatings. There exists a need for low manufacturing cost and rapid delivery of such handheld displays and therefore a low-cost, high-volume manufacturing process for producing high performance scratch-resistant optical coatings is desired for both 2D and 3D cover substrates. Such manufacturing processes include vacuum coating processes in which the substrates reach a significant temperature due to particle kinetics over the process duration (e.g., up to or even exceeding 230° C.), which makes clamping the substrates difficult with conventional techniques, such as adhesive tapes.

In known manufacturing processes, a tape having adhesive applied to both sides (i.e., a double-sided tape such as polyimide tape available under the Kapton® trademark E. I. du Pont de Nemours and Company) is being used to attach the substrates to the carriers in the coating system. There are three distinct disadvantages to this method: (1) the taping process is labor intensive and increases the time to set up the carriers for the next run and (2) the adhesive outgases in the pristine plasma environment resulting in contamination, requiring the plasma process chamber to be cleaned periodically and adding more cost and time to the process, and, (3) the adhesive leaves residue on the coated substrates which requires additional handling and cleaning post-coating, also adding further costs and time to the process.

Several methods to bond substrates (in particular, glass substrates) temporarily for processing have been tried in industry without significant success, such as glass-to-glass Van der Waals bonding, adhesive bonding with various adhesive compositions such as the polyimide adhesive tape previously mentioned being currently used in production, and polymeric coating on the glass surfaces to change the surface energy resulting in a temporary bond remaining strong enough for the contemplated end process but weak enough to de-bond once the process is complete. These are a few examples of clamping or holding methods and each have their drawbacks. For example, adding a thin film polymerized coating onto a carrier surface to change the surface energy requires a physical vapor deposition (PVD) or chemical vapor deposition (CVD) system to produce the required thin film and is in itself a significantly expensive process. This thin film coating on a carrier needs to be stripped and replaced at certain process run intervals, adding to further cost and complexity.

Accordingly, it can be seen that a need yet remains for a satisfactory low-cost technique for attaching cover substrates to carriers in order to coat the cover substrates in a vacuum deposition process (in particularly, a PVD process). It is to the provision of such that the present disclosure is primarily directed.

### SUMMARY

Briefly described, in a first example form the present disclosure relates to a chucking apparatus for vacuum processing mobile device cover substrates in a vacuum chamber. The chucking apparatus is configured for temporarily securing the cover substrate within the vacuum chamber, and includes a carrier substrate with a coefficient of thermal expansion (CTE) sufficiently closely matching the CTE of the cover substrate to prevent the carrier substrate and the cover substrate from becoming detached from one another due to differing rates of thermal expansion during processing in the vacuum chamber. In one or more embodiments, the CTE value of the cover substrate and the carrier substrate is within 20% of one another (e.g., within 18% of one another, 16% of one another, 15% of one another, 14% of one another, 12% of one another, 10% of one another, 8% of one another, 6% of one another, 5% of one another, 4% of one another, 2% of one another, or 1% of one another). The carrier substrate has a surface contact area in contact with the cover substrate selected to provide for continuous bonding during the processing in the vacuum chamber and to provide for de-bonding after the process in the vacuum chamber is complete. Further, the carrier substrate may include a surface contact area that comprises a surface that facilitates Van der Waals bonding between the carrier substrate and the cover substrate, while avoiding permanent bonding. This surface may be prepared by a cleaning process as described herein, according to one or more embodiments.

In one or more embodiments, the chucking apparatus includes a carrier frame and the carrier substrate is secured to the carrier frame. In one or more embodiments, the carrier substrate has a CTE substantially equal to that of the cover substrate. For example, the CTE value of the cover substrate and the carrier substrate is within 20% of one another (e.g., within 18% of one another, 16% of one another, 15% of one another, 14% of one another, 12% of one another, 10% of one another, 8% of one another, 6% of one another, 5% of one another, 4% of one another, 2% of one another, or 1% of one another). Optionally, the carrier substrate and the cover substrate have substantially the same material composition. In one or more embodiments, the carrier substrate and the cover substrate comprise glass materials.

Optionally, the cover substrate is curved cover substrate for hand-held devices and includes a substantially flat portion and the carrier substrate is smaller than the curved cover substrate and engages with the substantially flat portion of the cover substrate.

In one or more embodiments, the carrier substrate has a low mass, relative to the cover substrate, to reduce heat retention and thus to avoid permanent bonding of the cover substrate to the carrier substrate. Preferably, the carrier substrate has a mass of between about 6 and 8 grams.

In one or more embodiments, the carrier substrate has a thickness of between about 0.5 mm and about 0.6 mm. In one or more specific embodiments, the carrier substrate has a thickness of about 0.55 mm. Alternatively, the carrier substrate has a thickness of between about 1.5 mm and about 4.0 mm.

Optionally, the carrier substrate includes openings for allowing tooling to de-bond the carrier substrate from the carrier frame.

One or more embodiments of the method for coating mobile device cover substrates in a vacuum coating chamber includes the steps of:

a. Providing a plurality of carriers for temporarily mounting cover substrates to the rotating drum for coating the cover substrates;
b. Providing the carriers with Van der Waals (VdW) chucks, the VdW chucks including carrier substrates;
c. Cleaning the carrier substrates in preparation for use;
d. Cleaning the cover substrates in preparation for use, wherein the cleaning of the carrier substrates and the cleaning of the cover substrates is carried out in a manner to facilitate VdW bonding; and
e. Mounting the cover substrates to the carrier substrates while the carriers.

In one or more embodiments, mounting the cover substrates to the carrier substrates occurs outside the coating chamber, and the method further includes the steps of placing the carriers in the vacuum chamber; operating the vacuum chamber to carry out a coating operation on the mobile device cover substrates; removing the carriers; and removing the cover substrates from the carriers.

In one or more embodiments, the carrier substrates and the cover substrates are cleaned with detergent in a manner to control the amount of organic material on the carrier substrates and on the carrier substrates to facilitate VdW bonding, while avoiding permanent bonding.

In one or more embodiments, the carrier substrates and the cover substrates are cleaned with detergent in a manner to control the amount of organic material on the carrier substrates and on the carrier substrates to control the strength and permanence of the VdW bonding.

In one or more embodiments, the cover substrates are cleaned with detergent, and the carrier substrates are first cleaned with detergent and then cleaned with ozone dissolved in de-ionized water followed by cleaning with an ammonia-based solution.

In one or more embodiments, the method further includes cleaning the carrier substrates with a process comprising the steps of:

a. Cleaning the carrier substrates with ozone dissolved in de-ionized water;
b. Cleaning the carrier substrates with an ammonia-based solution;
c. Rinsing the carrier substrates with de-ionized water; and
d. Drying the carrier substrates.

In one or more embodiments, the step of cleaning the carrier substrates and the cover substrates with detergent comprises the steps of:

a. Rinsing with de-ionized water;
b. Ultrasonically cleaning in a detergent bath;
c. Rinsing with de-ionized water;
d. Rinsing with de-ionized water while ultrasonically cleaning;
e. Rinsing with de-ionized water; and
f. Drying with hot air.

Optionally, the cover substrates are initially secured to the chuck at least partly with electrostatic chucking while outside the vacuum chamber and then are transferred to the vacuum chamber wherein the VdW bonding provides the majority of the force securing the cover substrates to the carrier substrates.

In another example embodiment, the present disclosure relates to a manufacturing method for coating mobile device cover substrates with a coating in which the coating is applied via a sputtering plasma process in which the cover substrates are temporarily mounted on a rotating drum as the coating is delivered. The improvement therein comprises chucking the cover substrates with a Van der Waals (VdW) chuck on carriers to be temporarily secured to the rotating drum, with the cover substrates being secured temporarily to the VdW chucks by VdW forces.

Defined another way, the present disclosure can be considered the application of Van der Waal forces bonding between 2D and 3D cover substrate substrates and a substrate carrier by means of a interfacing surface preparation via cleaning, selection of specific substrate compositions and CTE matching with appropriate degree of surface roughness on the carrier, and compression process to provide a high contact area bond for the duration of holding the cover substrate uniformly flat in position during a coating process and impermanent enough to permit debonding once the coating process is complete.

Optionally, the Van der Waals chuck can be combined with an electrostatic chuck (ESC chuck). In this way, two very different chucking technologies can be employed in tandem, with neither one being required to bear the entire chucking load. An electrostatic chucking apparatus for such tandem use can include a carrier including a liquid-cooled cold plate which is removably mountable to the rotating drum. In the case of a 3D cover substrate, the carrier can include a portion with a 3D profile to match a 3D profile of the 3D cover substrate. The carrier further can include an electrostatic chuck adapted to secure the cover substrate in place against the carrier in the face of centrifugal forces caused by rotation of the rotating drum, with the ESC developing a sufficient clamping force for reliably securing the cover substrate in place, alone or in combination with the VdW chuck.

The cover substrate and the carrier substrate used in various embodiments may include an amorphous substrate or a crystalline substrate. An example of an amorphous substrate includes glass that may be selected from the group consisting of soda lime glass, alkali aluminosilicate glass, alkali containing borosilicate glass and alkali aluminoborosilicate glass. In some embodiments, the glass may be strengthened and may include a compressive stress (CS) layer with a surface CS of at least 250 MPa extending within the strengthened glass from a surface of the chemically strengthened glass to a depth of layer (DOL) of at least about 10 μm.

### BRIEF DESCRIPTION OF THE DRAWING FIGURES

FIG. 1 is a schematic illustration of a number of chucking apparatuses for coating cover substrate in a coating chamber having a rotating drum according to one or more embodiments.

FIG. 2 is a schematic, perspective illustration of an illustrative chucking apparatus of FIG. 1, showing a 2-D cover substrate mounted thereon.

FIG. 3 is a perspective illustration of a 3-D cover substrate and depicting the portion thereof to be chucked with a chucking apparatus according to the present disclosure.

FIG. 4A is a schematic illustration of a portion of a chucking apparatus of FIG. 1, including a substrate carrier for chucking a 2-D cover substrate mounted thereon.

FIG. 4B is a schematic illustration of a portion of a chucking apparatus of FIG. 1, including a glass carrier for chucking a 2-D cover glass mounted thereon.

FIG. 4C is a schematic illustration of a portion of a chucking apparatus of FIG. 1, including an aluminum base frame and a substrate carrier for chucking a 2-D cover substrate mounted thereon.

FIG. 5A is a schematic illustration of a portion of a chucking apparatus of FIG. 1 in a modified form, including a substrate carrier for chucking a 2-D cover substrate mounted thereon.

FIG. 5B is a schematic illustration of a chucking apparatus of FIG. 1 in a modified form, including a glass carrier for chucking a 2-D cover glass mounted thereon.

FIG. 5C is a schematic illustration of a c chucking apparatus of FIG. 1 in a modified form, in a modified form, including an aluminum base frame and a substrate carrier for chucking a 2-D cover substrate mounted thereon.

FIG. 6 is a schematic diagram of a first cleaning process for using the chucking apparatus of FIG. 1.

FIG. 7 is a schematic diagram of a detergent cleaning step of the cleaning process of FIG. 6.

FIG. 8 is a schematic diagram of a second cleaning process for using the chucking apparatus of FIG. 1.

FIG. 9 is a schematic diagram of a cleaning step of the cleaning process of FIG. 8.

FIGS. 10A and 10B are a pair of images of experimental test results showing the extent of Van der Waals bonding, with dark regions depicting non-bonded regions.

FIGS. 11A and 11B and 12A and 12B are images of experimental test results showing the extent of Van der Waals bonding, with diffraction ring regions depicting non-bonded regions.

### DETAILED DESCRIPTION

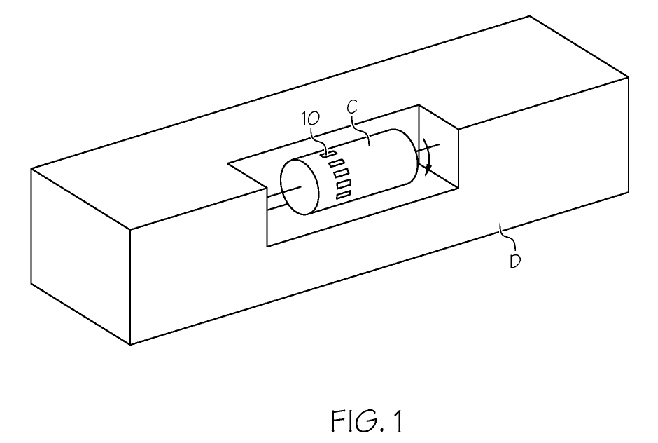

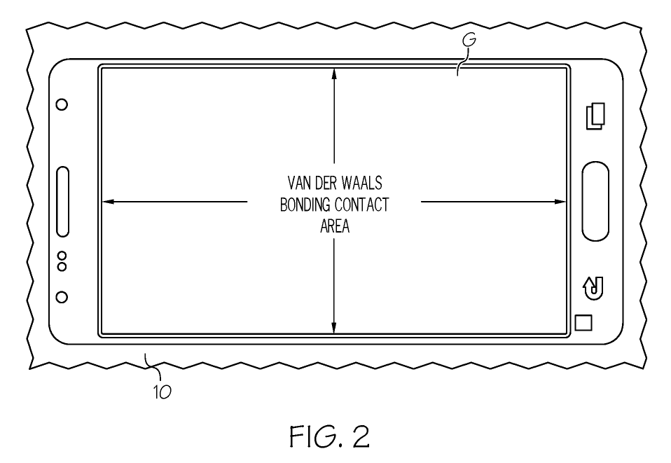

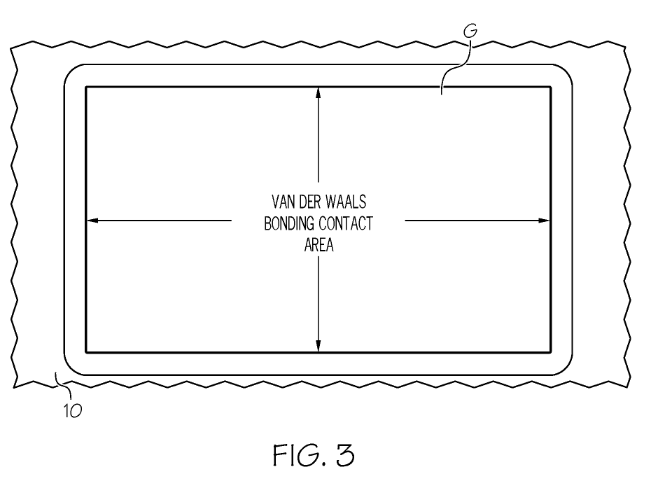

Referring now in detail to the various drawing figures, in which like reference characters represent like parts throughout the several views, FIG. 1 shows a plurality of chucking apparatuses 10 for coating cover substrate in a coating chamber C having a rotating drum D. The embodiments described herein makes use of Van der Waals forces to hold a 2D and 3D cover substrate on either a thin carrier (0.55 mm) or thick carrier (>1.5 mm, <4.0 mm). The cover substrate designs, such as the 2D cover substrate of FIG. 2 may have a decorated area as shown in the region of the arrows in FIG. 2, generally requiring the bonding portion of the carrier to be smaller in area than the cover substrate. In the case of a 3D part (as shown in FIG. 3), the internal flat area of the cover substrate is the area to be temporarily bonded so that the bonding portion of the carrier should be smaller than the cover substrate.

The mass of the carrier is selected so as to produce enough thickness to allow it to be retained by a mechanical clamp fixture, but at the same time being of insufficient mass to act as an effective heat sink (which would result in a permanent bond between it and the cover substrate at process temperatures). As the mass and heat retention rises, permanent bonding between the cover substrate and thick carrier is the result (outcome). Due to its low mass, the thin substrate carrier 10, even at an elevated temperature, does not experience this permanent bonding effect. The mass of the thin carrier substrate may be in a range of 6 to 8 grams.

The carrier 10 described in this disclosure has a particular composition with similar CTE (coefficient of thermal expansion) closely matched to that of the cover substrate G (which prevents bowing or billowing when exposed to process temperature) used in a process from between about 20° C. and <250° C. with Van der Waals forces which permit temporary bonding during a physical vapor deposition process to coat the cover substrate G on a rotating drum D. Cover substrate compositions may include an amorphous substrate or a crystalline substrate. An example of an amorphous substrate includes glass that may be selected from the group consisting of soda lime glass, alkali aluminosilicate glass, alkali containing borosilicate glass and alkali aluminoborosilicate glass. In some embodiments, the glass may be strengthened and may include a compressive stress (CS) layer with a surface CS of at least 250 MPa extending within the strengthened glass from a surface of the chemically strengthened glass to a depth of layer (DOL) of at least about 10 μm. Those skilled in the art will recognize that other cover compositions can be used with the present disclosure. A substantial CTE differential between the cover substrate G and the carrier 10 will cause different rates of thermal expansion between the carrier substrate and the cover substrate and could result in bowing of one or the other as the process temperature increases. Thus, the CTE of the cover substrate and the carrier substrate may be selected to be numerically close to one another. In one or more embodiments, the carrier comprises a glass composition matching the cover substrate (make them of the same composition). For example, the carrier may comprise the same or substantially same glass composition as the cover substrate.

Below are some glass compositions properties which could be used with the present invention, listing the CTE in the 0 to 300° C. range:

| Glass designation | E-mod | Poisson | CTE | Bow, μm |
|---|---|---|---|---|
| A | 65.79 | 0.22 | 86.9 | 17.9 |
| B | 71.70 | 0.21 | 83.0 | 407.0 |
| C | 68.02 | 0.22 | 76.0 | 917.0 |

The substrate used for the carrier substrate and/or the cover substrate may include an inorganic material and may include an amorphous substrate, a crystalline substrate or a combination thereof. The substrate used for the carrier substrate and/or the cover substrate may be formed from man-made materials and/or naturally occurring materials (e.g., quartz and polymers). For example, in some instances, the substrate may be characterized as organic and may specifically be polymeric.

In some specific embodiments, the substrate may specifically exclude polymeric, plastic and/or metal substrates. The substrate may be characterized as alkali-including substrates (i.e., the substrate includes one or more alkalis).

In one or more embodiments, the substrate exhibits a refractive index in the range from about 1.45 to about 1.55. In specific embodiments, the substrate may exhibit an average strain-to-failure at a surface on one or more opposing major surface that is 0.5% or greater, 0.6% or greater, 0.7% or greater, 0.8% or greater, 0.9% or greater, 1% or greater, 1.1% or greater, 1.2% or greater, 1.3% or greater, 1.4% or greater 1.5% or greater or even 2% or greater, as measured using ball-on-ring testing using at least 5, at least 10, at least 15, or at least 20 samples. In specific embodiments, the substrate may exhibit an average strain-to-failure at its surface on one or more opposing major surface of about 1.2%, about 1.4%, about 1.6%, about 1.8%, about 2.2%, about 2.4%, about 2.6%, about 2.8%, or about 3% or greater.

Suitable substrates may exhibit an elastic modulus (or Young's modulus) in the range from about 30 GPa to about 120 GPa. In some instances, the elastic modulus of the substrate may be in the range from about 30 GPa to about 110 GPa, from about 30 GPa to about 100 GPa, from about 30 GPa to about 90 GPa, from about 30 GPa to about 80 GPa, from about 30 GPa to about 70 GPa, from about 40 GPa to about 120 GPa, from about 50 GPa to about 120 GPa, from about 60 GPa to about 120 GPa, from about 70 GPa to about 120 GPa, and all ranges and sub-ranges therebetween.

In one or more embodiments, the substrate may be an amorphous substrate, which may include glass. In one or more embodiments, the glass substrate may be strengthened or non-strengthened. Examples of suitable glass include soda lime glass, alkali aluminosilicate glass, alkali containing borosilicate glass and alkali aluminoborosilicate glass. In some variants, the glass may be free of lithia. In one or more alternative embodiments, the substrate may include crystalline substrates such as glass ceramic substrates (which may be strengthened or non-strengthened) or may include a single crystal structure, such as sapphire. In one or more specific embodiments, the substrate includes an amorphous base (e.g., glass) and a crystalline cladding (e.g., sapphire layer, a polycrystalline alumina layer and/or or a spinel (MgAl₂O₄) layer).

The substrate may be substantially optically clear, transparent and free from light scattering. In such embodiments, the substrate may exhibit an average light transmission over the optical wavelength regime of about 85% or greater, about 86% or greater, about 87% or greater, about 88% or greater, about 89% or greater, about 90% or greater, about 91% or greater or about 92% or greater. In one or more alternative embodiments, the substrate may be opaque or exhibit an average light transmission over the optical wavelength regime of less than about 10%, less than about 9%, less than about 8%, less than about 7%, less than about 6%, less than about 5%, less than about 4%, less than about 3%, less than about 2%, less than about 1%, or less than about 0%. In some embodiments, these light reflectance and transmittance values may be a total reflectance or total transmittance (taking into account reflectance or transmittance on both major surfaces of the substrate) or may be observed on a single side of the substrate. Unless otherwise specified, the average reflectance or transmittance is measured at an incident illumination angle of 0 degrees (i.e. normal incidence), 5 degrees from normal incidence or 8 degrees from normal incidence. The substrate may optionally exhibit a color, such as white, black, red, blue, green, yellow, orange etc.

Additionally or alternatively, the physical thickness of the substrate may vary along one or more of its dimensions for aesthetic and/or functional reasons. For example, the edges of the substrate may be thicker as compared to more central regions of the substrate. The length, width and physical thickness dimensions of the substrate may also vary according to the application or use of the article.

Once formed, a substrate may be strengthened to form a strengthened substrate. As used herein, the term “strengthened substrate” may refer to a substrate that has been chemically strengthened, for example through ion-exchange of larger ions for smaller ions in the surface of the substrate. However, other strengthening methods known in the art, such as thermal tempering, or utilizing a mismatch of the coefficient of thermal expansion between portions of the substrate to create compressive stress and central tension regions, may be utilized to form strengthened substrates.

Where the substrate is chemically strengthened by an ion exchange process, the ions in the surface layer of the substrate are replaced by—or exchanged with—larger ions having the same valence or oxidation state. Ion exchange processes are typically carried out by immersing a substrate in a molten salt bath containing the larger ions to be exchanged with the smaller ions in the substrate. It will be appreciated by those skilled in the art that parameters for the ion exchange process, including, but not limited to, bath composition and temperature, immersion time, the number of immersions of the substrate in a salt bath (or baths), use of multiple salt baths, additional steps such as annealing, washing, and the like, are generally determined by the composition of the substrate and the desired compressive stress (CS), depth of compressive stress layer (or depth of layer) of the substrate that result from the strengthening operation. By way of example, ion exchange of alkali metal-containing glass substrates may be achieved by immersion in at least one molten bath containing a salt such as, but not limited to, nitrates, sulfates, and chlorides of the larger alkali metal ion. The temperature of the molten salt bath typically is in a range from about 380° C. up to about 450° C., while immersion times range from about 15 minutes up to about 40 hours. However, temperatures and immersion times different from those described above may also be used.

The degree of chemical strengthening achieved by ion exchange may be quantified based on the parameters of central tension (CT), surface CS, and depth of layer (DOL). Surface CS may be measured near the surface or within the strengthened glass at various depths. A maximum CS value may include the measured CS at the surface (CSₛ) of the strengthened substrate. The CT, which is computed for the inner region adjacent the compressive stress layer within a glass substrate, can be calculated from the CS, the physical thickness t, and the DOL. CS and DOL are measured using those means known in the art. Such means include, but are not limited to, measurement of surface stress (FSM) using commercially available instruments such as the FSM-6000, manufactured by Luceo Co., Ltd. (Tokyo, Japan). Surface stress measurements rely upon the accurate measurement of the stress optical coefficient (SOC), which is related to the birefringence of the glass substrate. SOC in turn is measured by those methods that are known in the art, such as fiber and four point bend methods, both of which are described in ASTM standard C770-98 (2008), entitled “Standard Test Method for Measurement of Glass Stress-Optical Coefficient,” the contents of which are incorporated herein by reference in their entirety, and a bulk cylinder method. The relationship between CS and CT is given by the expression (1):

CT=(CS·DOL)/(t−2DOL) (1),

wherein t is the physical thickness (μm) of the glass article. In various sections of the disclosure, CT and CS are expressed herein in megaPascals (MPa), physical thickness t is expressed in either micrometers (μm) or millimeters (mm) and DOL is expressed in micrometers (μm).

In one embodiment, a strengthened substrate can have a surface CS of 250 MPa or greater, 300 MPa or greater, e.g., 400 MPa or greater, 450 MPa or greater, 500 MPa or greater, 550 MPa or greater, 600 MPa or greater, 650 MPa or greater, 700 MPa or greater, 750 MPa or greater or 800 MPa or greater. The strengthened substrate may have a DOL of 10 μm or greater, 15 μm or greater, 20 μm or greater (e.g., 25 μm, 30 μm, 35 μm, 40 μm, 45 μm, 50 μm or greater) and/or a CT of 10 MPa or greater, 20 MPa or greater, 30 MPa or greater, 40 MPa or greater (e.g., 42 MPa, 45 MPa, or 50 MPa or greater) but less than 100 MPa (e.g., 95, 90, 85, 80, 75, 70, 65, 60, 55 MPa or less). In one or more specific embodiments, the strengthened substrate has one or more of the following: a surface CS greater than 500 MPa, a DOL greater than 15 μm, and a CT greater than 18 MPa.

Where the substrate includes a crystalline substrate, the substrate may include a single crystal, which may include Al₂O₃. Such single crystal substrates are referred to as sapphire. Other suitable materials for a crystalline substrate include polycrystalline alumina layer and/or spinel (MgAl₂O₄).

Optionally, the crystalline substrate may include a glass ceramic substrate, which may be strengthened or non-strengthened. Examples of suitable glass ceramics may include Li₂O—Al₂O₃—SiO₂ system (i.e. LAS-System) glass ceramics, MgO—Al₂O₃—SiO₂ system (i.e. MAS-System) glass ceramics, and/or glass ceramics that include a predominant crystal phase including β-quartz solid solution, β-spodumene ss, cordierite, and lithium disilicate. The glass ceramic substrates may be strengthened using the chemical strengthening processes disclosed herein. In one or more embodiments, MAS-System glass ceramic substrates may be strengthened in Li₂SO₄ molten salt, whereby an exchange of 2Li⁺ for Mg²⁺ can occur.

The substrate according to one or more embodiments can have a physical thickness ranging from about 100 μm to about 5 mm. Example substrate physical thicknesses range from about 100 μm to about 500 μm (e.g., 100, 200, 300, 400 or 500 μm). Further example substrate physical thicknesses range from about 500 μm to about 1000 μm (e.g., 500, 600, 700, 800, 900 or 1000 μm). The substrate may have a physical thickness greater than about 1 mm (e.g., about 2, 3, 4, or 5 mm). In one or more specific embodiments, the substrate may have a physical thickness of 2 mm or less or less than 1 mm. The substrate may be acid polished or otherwise treated to remove or reduce the effect of surface flaws.

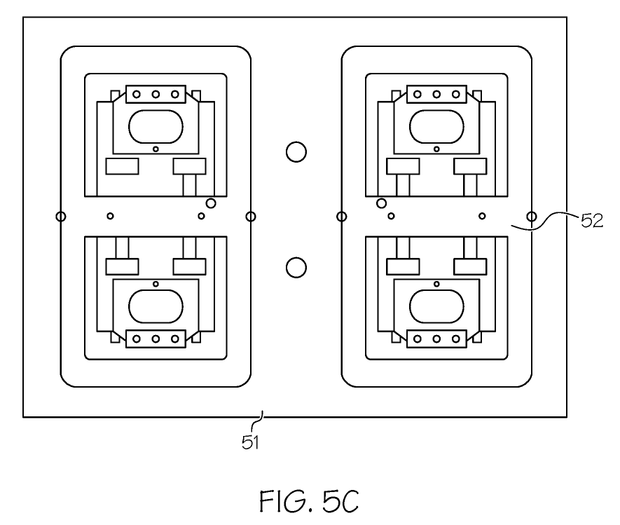

To prepare the surfaces for Van der Waals forces bonding, a cleaning process is helpful to remove organics and particulates which would otherwise prevent bonding by maintaining a separation between the two surfaces when one brings the cover substrate against the carrier substrate. This is shown generally in FIGS. 6-9. In one or more embodiments, some, but not all, such foreign matter is removed from the mating surfaces to facilitate temporary (but not permanent) bonding.

As depicted in FIG. 6, to accomplish this, the substrates are cleaned according to process 60, with the thin carrier substrate being detergent cleaned to ready for bonding at step 61. The cover substrate gets the same detergent cleaning process at step 62. The cover substrate and the thin carrier can then be brought together to bond them together with VdW forces at step 64.

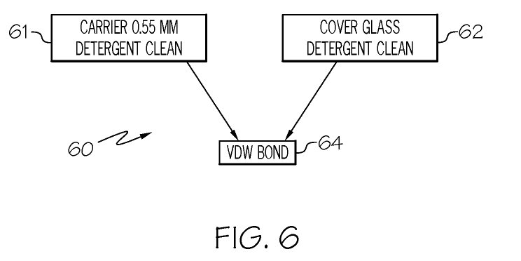

The details of the detergent cleaning method (61, 62) are shown in FIG. 7, in steps 71-76. Step 71 represents a de-ionized water rinse shower at 71° C. for 13 minutes. Step 72 represents a 40 kHz ultrasonic detergent bath at 71° C. for 12 minutes. Step 73 represents a de-ionized water rinse shower at 71° C. for 13 minutes. Step 74 represents a second 40 kHz ultrasonic detergent bath at 71° C. for 12 minutes. Step 75 represents a slow pull de-ionized water rinse bath at 71° C. for 12 minutes. Step 76 represents a forced hot air drying step for 12 minutes. Other combinations of rinsing, detergent, and drying steps, at different temperatures and different durations, may be found to work. But the above combination of steps has been found to work well.

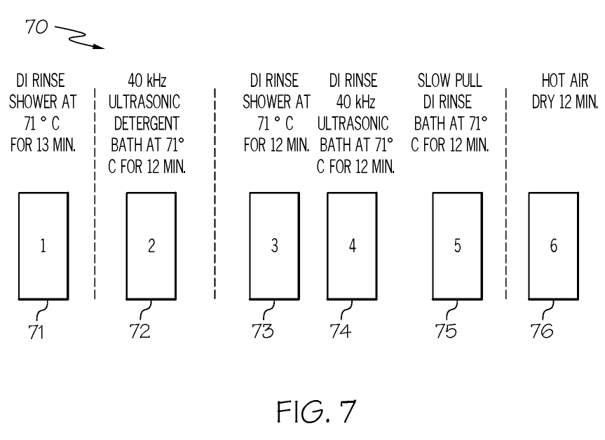

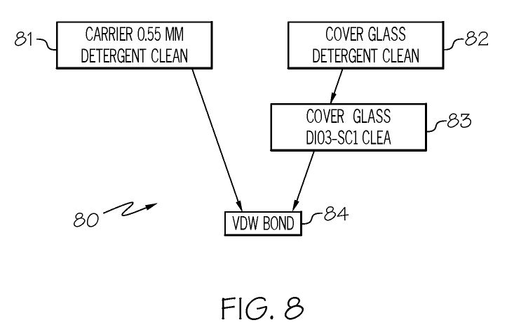

In case of thick carrier substrate (between 1.5 mm and 4.0 mm), due to surface chemistry, the carrier is detergent cleaned, but in addition is cleaned with a dissolved ozone and a surface cleaning process. These process steps are shown in FIGS. 8-9. As shown in FIG. 8, the cleaning process includes that the cover substrate is detergent cleaned at step 81 and the carrier substrate is detergent cleaned at step 82. In one or more embodiments, these detergent cleaning steps 81, 82 use the detergent cleaning process shown in FIG. 7. In addition, the cover substrate is further cleaned with an additional cleaning step, as mentioned above, at step 83 with a dissolved ozone and a surface cleaning process. Then the carrier substrate 10 and the cover substrate G are brought together to obtain a temporary VdW bond. Post-cleaning, the bonding process results in a high degree of bond contact area, achieving bonding area results of greater than 90%.

The step 83 is a multi-step cleaning process 90 as shown in FIG. 9. Process 90 includes step 91 in which dissolved ozone (in de-ionized water) bathes the substrate at 17° C. to 21° C. for 10 minutes. At step 92, in the surface cleaning process labeled “SC1” NH₄OH+H₂O₂ bathes the substrate at 65° C. for 10 minutes. Step 93 represents a de-ionized water rinse shower at 17-21° C. for 12 minutes. Finally, step 94 represents a Marangoni drying step at 17-21° C. for 14 minutes. Again, other combinations of rinsing, cleaning, and drying steps, at different temperatures and different durations, may be found to work. But the above combination of steps has been found to work well.

A careful selection of surface roughness is helpful to provide a desired degree of contact between the cover substrate molecules and the carrier substrate molecules so as to yield sufficient Van der Waals bonding. However, the surface roughness should not be too smooth, otherwise permanent bonding can occur. Thus, the surface roughness should be chosen to be rough enough to prevent permanent bonding at the elevated process temperature, but smooth enough to result in temporary Van der Waals bonding. Similarly, the substrate surfaces should be clean, but not too clean, so as to obtain only temporary bonding (and not permanent bonding).

A cover substrate made with an aluminosilicate glass composition has a surface roughness of Rq=0.59 nm and Ra=0.47 nm and its flatness is <80 μm. These values are for the normal production of such aluminosilicate cover glass. However, the selection of the surface roughness and flatness of the carrier substrate is chosen to produce the Van der Waals bonding to retain the substrate during the coating process but permit debonding post-process. The desired carrier substrate for use therewith may have a roughness range of <0.6 μm and a flatness of <60 μm.

Contact area as used herein is defined as the carrier substrate surface area that is VdW-bonded to the cover substrate. The contact need not take up the entire area, as shown in FIGS. 2 and 3, but can be smaller depending on the mass of the cover substrate and the desired bond strength to keep it bonded during the coating process. More contact area equates to higher holding force during the coating operation with the bond strength typically stated in g/cm². The cover substrate G in FIG. 2 weighs 7.9 g and the cover substrate G in FIG. 3 weighs 18 g. A drum coater may, for instance, have a drum diameter of 1.5 m and may spin at 100 RPM. The circumference is then 4.7 m and the rotations per second (RPS)=100/60=1.7 RPS. This yields a velocity, v=4.7 m/1.7 RPS=2.8 m/s, which is the linear velocity. The centrifugal force is then:

For the 7.9 g cover substrate:

F_{c}=m(nω/60)²/r=7.9×10⁻³ kg(100*2*π*0.75 m/60)²/0.75 m=0.65 N

If the contact area is 5.5 cm×10 cm or 55 cm², then the area=0.0055 m² then, 0.65 N/0.0055 m²=118.2 N/m²=1.21 g/cm², which is the minimum bond strength required to hold the part as it spins on the outside of a 1.5 m diameter drum rotating at 100 RPM.

For the 18 g cover substrate:

F_{c}=m(nω/60)²/r=18.0×10⁻³ kg(100*2*π*0.75 m/60)²/0.75 m=1.48 N.

If the contact area is 7 cm×12 cm or 84 cm² then the area=0.0084 m² then

1.48N/0.0084 m²=176.2 N/m²=1.8 g/cm².
This is the minimum bond strength required to hold the part as it spins on the outside of a 1.5 m diameter drum rotating at 100 RPM.

If the contact area between the carrier substrate and the cover substrate is reduced, the required clamping force per square should be increased. Likewise, if the mass of the cover substrate is increased but the contact area remains the same, then the required clamping force per square area should also be increased.

To achieve the increased bonding strength, the contact area can be increased, combined perhaps with a change in carrier surface roughness (smoothing will increase the bonding strength) and carrier flatness (provides more uniform contact). These are three variables that can be adjusted to increase/decrease the Van der Waals bond strength as required by the particular coating process drum speed, mass of the cover substrate, and available cover substrate flat area for bonding.

Thus, the composition and size of the 2D and 3D cover substrate determines the characteristics of the carrier substrate and determines the selection of the carrier substrate composition as it pertains to CTE. Once the material is selected and the carrier has been cut and machined to the required process dimensions, the detergent and dissolved ozone and SC1 cleaning process can be employed (with the optional Marangoni drying process). At this point the two substrate surfaces (the carrier substrate and cover substrate) can be bonded together with Van der Waals forces.

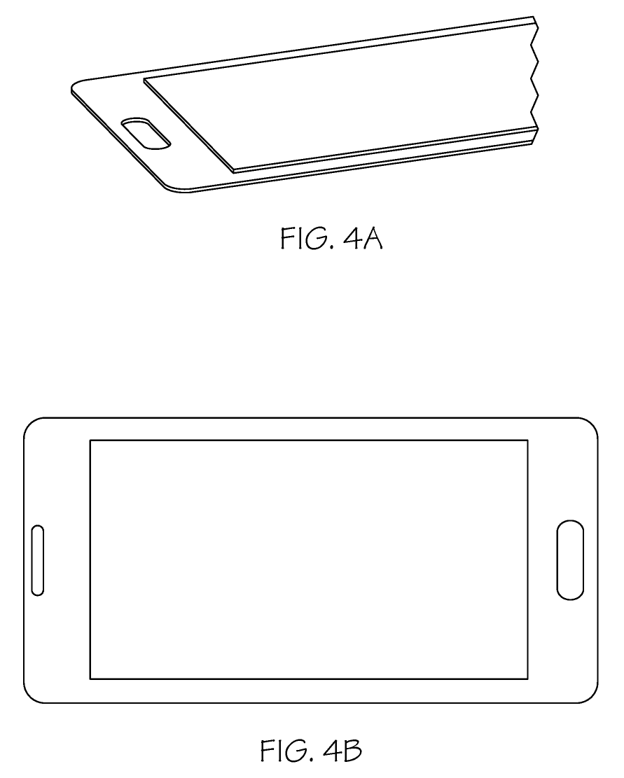

FIGS. 4A and 4B are schematic illustrations of a portion of a chucking apparatus of FIG. 1, including a glass carrier for chucking a 2-D cover glass mounted thereon. FIG. 4C is a schematic illustration of a portion 40 of a chucking apparatus of FIG. 1, including an aluminum base frame 41 and a glass carrier 42 for chucking a 2-D cover glass mounted thereon. An illustrative embodiment shown in these figures uses a thin carrier glass with thickness ranging from 0.4 mm to 1 mm thickness in which the thin carrier is attached to a mechanical frame. Such a frame typically can be made from aluminum and the frame is mechanically attachable to the PVD coating system platform, i.e., a rotary drum, carousel, or table, depending on the type of PVD system being used.

The carrier may be attached to the metal frame by adhesive means, such as polyimide double-sided tape or a high-temperature polymer bonded between the carrier glass and the metal frame. The tape method is shown in FIGS. 4A, 4B and 4C. FIG. 4C shows a thin glass carrier having the composition of A that is Van der Waals bonded to a cover glass substrate having the same composition as the glass carrier and its mounting frame (and showing the double-sided tape holding the carrier to the aluminum frame). The holes (e.g., hole 46) in the aluminum frame permit push rods (not shown) to push up on carrier glass to remove it from the tape 44 once coating is complete.

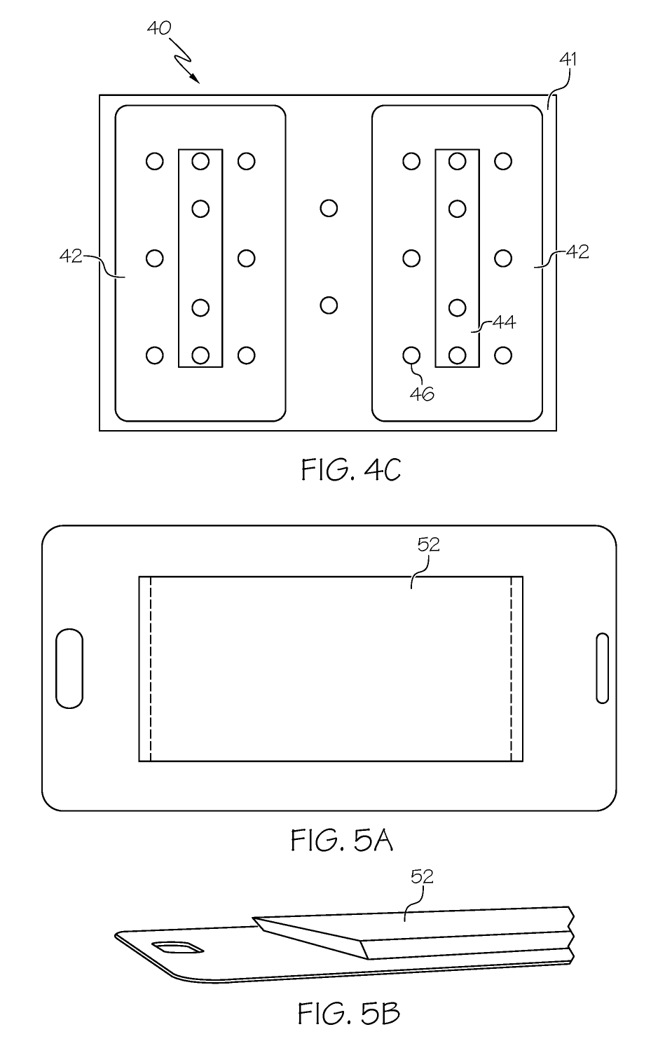

FIGS. 5A and 5B are schematic illustrations of a portion 50 of a chucking apparatus of FIG. 1 in a modified form, including a glass carrier 52 for chucking a 2-D cover glass mounted thereon. FIG. 5C is a schematic illustration of a chucking apparatus of FIG. 1 in a modified form, including an aluminum base frame 51 and a glass carrier 52 for chucking a 2-D cover glass mounted thereon. This additional embodiment uses a thick carrier having a thickness ranging from 2 mm to 4 mm and which has a chamfered edge permitting a mechanical spring-loaded frame to capture the carrier edge. The spring-loaded metal frame is mechanically attached to the PVD coating system platform, i.e. rotary drum, carousel, or table depending on the type of PVD system being used. This embodiment is typified by the edge clamping of the “wedge” glass carrier to the spring-loaded metal frame (see FIGS. 5A and 5B). This spring-loaded edge clamping technique is shown in FIG. 5B.

These two embodiments (FIGS. 4A-5C) are for illustration purposes and the use of glass-to-glass Van der Waal bonding is not limited to the particular example mountings shown in these figures, but may be of a variety of mounting methods as the particular application requires. These illustrative mounting frames were put on a rotary temperature test set up and spun at 210 RPM for 3 hours and demonstrated that the Van der Waals bonding of a thin carrier and a thick carrier could be maintained during such temperatures and spin rates. It was also demonstrated thereby that the carrier glass and the cover glass could be debonded after the spin test.

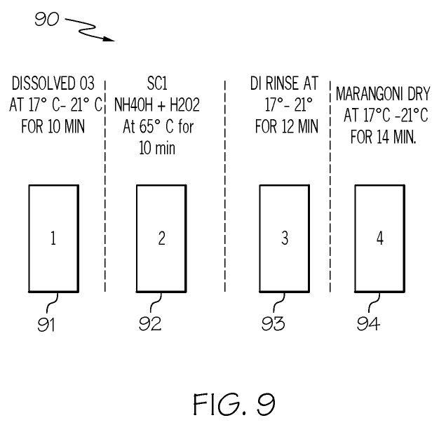

FIGS. 10A and 10B are a pair of images of experimental test results showing the extent of Van der Waals bonding, with dark regions depicting non-bonded regions.

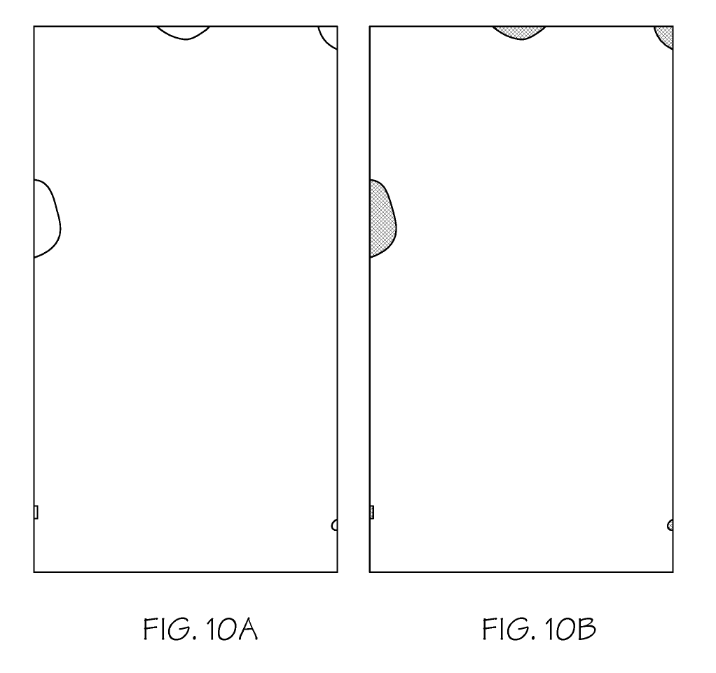

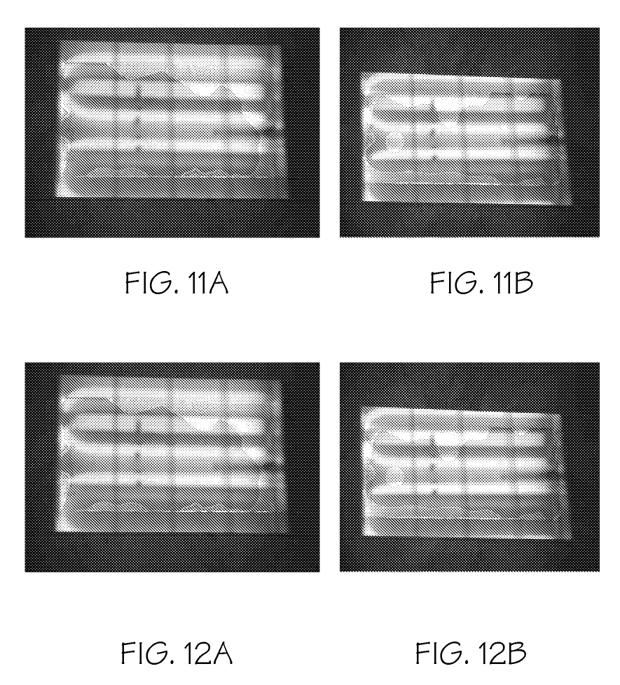

FIGS. 11A, 11B, 12A and 12B are images of experimental test results showing the extent of Van der Waals bonding, with diffraction ring regions depicting non-bonded regions.

Optionally, the Van der Waals chuck can be combined with an electrostatic chuck (ESC chuck). In this way, two different chucking technologies can be employed in tandem, with neither one being required to bear the entire chucking load. An electrostatic chucking apparatus for such tandem use can include a carrier including a liquid-cooled cold plate which is removably mountable to the rotating drum. In the case of a 3D cover substrate, the carrier can include a portion with a 3D profile to match a 3D profile of the 3D cover substrate. The carrier further can include an electrostatic chuck adapted to secure the cover substrate in place against the carrier in the face of centrifugal forces caused by rotation of the rotating drum, with the ESC developing a sufficient clamping force for reliably securing the cover substrate in place, alone or in combination with the VdW chuck.

Advantageously, the present inventors have discovered that despite the technical challenges found in PVD applications, careful design selection of CTE, surface roughness, surface preparation, and material composition can allow for good temporary bonding of cover substrates to carrier substrates using Van der Waals forces. In particular, one or more of the following, alone or in combination, has been found to be particularly advantageous: using Van der Waals temporary bonding of cover glass substrates to glass carriers as described herein makes use of the selection of carrier glass composition for appropriate CTE, selection of carrier glass mass to prevent heat retention and permanent bonding to the cover glass, the surface contact area of the carrier to provide continuous bonding during a vacuum process and debonding once the vacuum process is complete, cleaning preparation of the cover glass and carrier glass prior to bonding, and the appropriate selection of surface roughness to permit Van der Waals bonding (and debonding once the process is complete).

The adaptation of Van der Waals forces bonding to this glass coating application provides a low-cost production method to secure 2D and 3D cover substrates during the coating process. By contrast, the current production method of using double-sided tape bonding is both labor-intensive and costly. Moreover, the current production bonding process of using tape results in the tape adhesive outgassing in the plasma process environment, leading to costly plasma chamber cleaning every few runs. By contrast, the invention described herein avoids or minimizes contamination in the plasma environment. This results in less machine downtime and the associated costly loss of productivity.

Also, the current production bonding process with double-sided tape leaves a residue on the coated cover glass substrate, which requires careful (and expensive) cleaning and handling of the part so as not to damage the newly-applied coating or scratch the cover glass. The embodiments described herein eliminates this current post-coating process step and the associated risk of damaging the coated part.

While the disclosure has been described in terms of various illustrative embodiments, those skilled in the art will appreciate that various changes, additions, deletions, and modifications can be made therein without departing from the spirit and scope of the disclosure as defined in the appended claims. The various elements of the disclosure may be combined in any and all combinations, for example, as set forth in the following embodiments.

### Embodiment 1

A chucking apparatus for vacuum processing a cover substrate temporarily secured within a vacuum chamber, the chucking apparatus comprising:

a carrier substrate with a CTE value within 20% of a CTE value of the cover substrate;

wherein the carrier substrate has a surface contact area in contact with the cover substrate selected to provide for continuous bonding during the processing in the vacuum chamber and to provide for de-bonding after the process in the vacuum chamber is complete; and

wherein the carrier substrate comprises a cleaned surface that facilitates Van der Waals bonding between the carrier substrate and the cover substrate.

### Embodiment 2

A chucking apparatus as in Embodiment 1 further comprising a carrier frame and wherein the carrier substrate is secured to the carrier frame.

### Embodiment 3

A chucking apparatus as in Embodiment 1 or Embodiment 2 wherein the carrier substrate has a coefficient of thermal expansion (CTE) substantially equal to that of the cover substrate.

### Embodiment 4

A chucking apparatus as in Embodiment 3 wherein the carrier substrate and the cover substrate have substantially the same material composition.

### Embodiment 5

A chucking apparatus as in any one of Embodiments 1-4 wherein the cover substrate is curved cover substrate for hand-held devices and includes a substantially flat portion and wherein the carrier substrate is smaller than the curved cover substrate and engages with the substantially flat portion of the cover substrate.

### Embodiment 6

A chucking apparatus as in any one of Embodiments 1-5 wherein the carrier substrate has a low mass, relative to the cover substrate, to reduce heat retention and thus to avoid permanent bonding of the cover substrate to the carrier substrate.

### Embodiment 7

A chucking apparatus as in Embodiment 6 wherein the carrier substrate has a mass of between about 6 and 8 grams.

### Embodiment 8

A chucking apparatus as in Embodiment 6 or Embodiment 7 wherein the carrier substrate has a thickness of between about 0.5 mm and about 0.6 mm.

### Embodiment 9

A chucking apparatus as in Embodiment 6 or Embodiment 7 wherein the carrier substrate has a thickness of about 0.55 mm.

### Embodiment 10

A chucking apparatus as in any one of Embodiments 1-9 wherein the carrier substrate has a thickness of between about 1.5 mm and about 4.0 mm.

### Embodiment 11

A chucking apparatus as in any one of Embodiments 1-10 wherein the carrier substrate includes openings for allowing tooling to de-bond the carrier substrate from the carrier frame.

### Embodiment 12

A chucking apparatus as in any one of Embodiments 1-11 wherein the carrier substrate is cleaned with detergent prior to mounting a cover substrate thereon.

### Embodiment 13

A method for coating mobile device cover substrates in a vacuum coating chamber, the method comprising the steps of:

providing a plurality of carriers for temporarily mounting cover substrates to the rotating drum for coating the cover substrates;

providing the carriers with Van der Waals (VdW) chucks, the VdW chucks including carrier substrates;

cleaning the carrier substrates in preparation for use;

cleaning the cover substrates in preparation for use, wherein the cleaning of the carrier substrates and the cleaning of the cover substrates is carried out in a manner to facilitate VdW bonding; and

mounting the cover substrates to the carrier substrates while the carriers.

### Embodiment 14

A coating method as in Embodiment 13 wherein mounting the cover substrates to the carrier substrates occurs outside the coating chamber, the method further comprising the steps of placing the carriers in the vacuum chamber; operating the vacuum chamber to carry out a coating operation on the mobile device cover substrates; removing the carriers; and removing the cover substrates from the carriers.

### Embodiment 15

A coating method as in Embodiment 13 or Embodiment 14 wherein the carrier substrates and the cover substrates are cleaned with detergent in a manner to control the amount of organic material on the carrier substrates and on the carrier substrates to facilitate VdW bonding.

### Embodiment 16

A coating method as in any one of Embodiments 13-15 wherein the carrier substrates and the cover substrates are cleaned with detergent in a manner to control the amount of organic material on the carrier substrates and on the carrier substrates to control the strength and permanence of the VdW bonding.

### Embodiment 17

A coating method as in any one of Embodiments 13-16 wherein the cover substrates are cleaned with detergent; and wherein the carrier substrates are first cleaned with detergent and then cleaned with ozone dissolved in de-ionized water followed by cleaning with an ammonia-based solution.

### Embodiment 18

A coating method as in any one of Embodiments 13-16 further comprising cleaning the carrier substrates with a process comprising the steps of:

cleaning the carrier substrates with ozone dissolved in de-ionized water;

cleaning the carrier substrates with an ammonia-based solution;

rinsing the carrier substrates with de-ionized water; and

drying the carrier substrates.

### Embodiment 19

A coating method as in any one of Embodiments 13-16 wherein step of cleaning the carrier substrates and the cover substrates with detergent comprises the steps of:

rinsing with de-ionized water;

ultrasonically cleaning in a detergent bath;

rinsing with de-ionized water;

rinsing with de-ionized water while ultrasonically cleaning;

rinsing with de-ionized water; and

drying with hot air.

### Embodiment 20

A coating method as in any one of Embodiments 13-19 wherein the cover substrates are initially secured to the chuck at least partly with electrostatic chucking while outside the vacuum chamber and then are transferred to the vacuum chamber wherein the VdW bonding provides the majority of the force securing the cover substrates to the carrier substrates.

21. In a manufacturing method for coating mobile device cover substrates with a coating in which the coating is applied via a plasma-enhanced PVD process in which the cover substrates are temporarily mounted on a rotating drum as the coating is delivered, the improvement therein comprising:

chucking the cover substrates with a Van der Waals (VdW) chuck on carriers to be temporarily secured to the rotating drum, with the cover substrates being secured temporarily to the VdW chucks by VdW forces.

1. A chucking apparatus for vacuum processing a cover substrate temporarily secured within a vacuum chamber, the chucking apparatus comprising:
a carrier substrate with a CTE value within 20% of a CTE value of the cover substrate;
wherein the carrier substrate has a surface contact area in contact with the cover substrate selected to provide for continuous bonding during the processing in the vacuum chamber and to provide for de-bonding after the process in the vacuum chamber is complete; and
wherein the carrier substrate comprises a cleaned surface that facilitates Van der Waals bonding between the carrier substrate and the cover substrate.

2. A chucking apparatus as claimed in claim 1 further comprising a carrier frame and wherein the carrier substrate is secured to the carrier frame.

3. A chucking apparatus as claimed in claim 1 wherein the carrier substrate has a coefficient of thermal expansion (CTE) substantially equal to that of the cover substrate.

4. A chucking apparatus as claimed in claim 3 wherein the carrier substrate and the cover substrate have substantially the same material composition.

5. A chucking apparatus as claimed in claim 1 wherein the cover substrate is curved cover substrate for hand-held devices and includes a substantially flat portion and wherein the carrier substrate is smaller than the curved cover substrate and engages with the substantially flat portion of the cover substrate.

6. A chucking apparatus as claimed in claim 1 wherein the carrier substrate has a low mass, relative to the cover substrate, to reduce heat retention and thus to avoid permanent bonding of the cover substrate to the carrier substrate.

7. A chucking apparatus as claimed in claim 6 wherein the carrier substrate has a mass of between about 6 and 8 grams.

8. A chucking apparatus as claimed in claim 6 wherein the carrier substrate has a thickness of between about 0.5 mm and about 0.6 mm.

9. A chucking apparatus as claimed in claim 8 wherein the carrier substrate has a thickness of about 0.55 mm.

10. A chucking apparatus as claimed in claim 1 wherein the carrier substrate has a thickness of between about 1.5 mm and about 4.0 mm.

11. A chucking apparatus as claimed in claim 1 wherein the carrier substrate includes openings for allowing tooling to de-bond the carrier substrate from the carrier frame.

12. A chucking apparatus as claimed in claim 1 wherein the carrier substrate is cleaned with detergent prior to mounting a cover substrate thereon.

13. A method for coating mobile device cover substrates in a vacuum coating chamber, the method comprising the steps of:
providing a plurality of carriers for temporarily mounting cover substrates to the rotating drum for coating the cover substrates;
providing the carriers with Van der Waals (VdW) chucks, the VdW chucks including carrier substrates;
cleaning the carrier substrates in preparation for use;
cleaning the cover substrates in preparation for use, wherein the cleaning of the carrier substrates and the cleaning of the cover substrates is carried out in a manner to facilitate VdW bonding; and
mounting the cover substrates to the carrier substrates while the carriers.

14. A coating method as claimed in claim 13 wherein mounting the cover substrates to the carrier substrates occurs outside the coating chamber, the method further comprising the steps of placing the carriers in the vacuum chamber; operating the vacuum chamber to carry out a coating operation on the mobile device cover substrates; removing the carriers; and removing the cover substrates from the carriers.

15. A coating method as claimed in claim 13 wherein the carrier substrates and the cover substrates are cleaned with detergent in a manner to control the amount of organic material on the carrier substrates and on the carrier substrates to facilitate VdW bonding.

16. A coating method as claimed in claim 13 wherein the carrier substrates and the cover substrates are cleaned with detergent in a manner to control the amount of organic material on the carrier substrates and on the carrier substrates to control the strength and permanence of the VdW bonding.

17. A coating method as claimed in claim 13 wherein the cover substrates are cleaned with detergent; and wherein the carrier substrates are first cleaned with detergent and then cleaned with ozone dissolved in de-ionized water followed by cleaning with an ammonia-based solution.

18. A coating method as claimed in claim 13 further comprising cleaning the carrier substrates with a process comprising the steps of:
cleaning the carrier substrates with ozone dissolved in de-ionized water;
cleaning the carrier substrates with an ammonia-based solution;
rinsing the carrier substrates with de-ionized water; and
drying the carrier substrates.

19. A coating method as claimed in claim 13 wherein step of cleaning the carrier substrates and the cover substrates with detergent comprises the steps of:
rinsing with de-ionized water;
ultrasonically cleaning in a detergent bath;
rinsing with de-ionized water;
rinsing with de-ionized water while ultrasonically cleaning;
rinsing with de-ionized water; and
drying with hot air.

20. A coating method as claimed in claim 13 the cover substrates are initially secured to the chuck at least partly with electrostatic chucking while outside the vacuum chamber and then are transferred to the vacuum chamber wherein the VdW bonding provides the majority of the force securing the cover substrates to the carrier substrates.

21. In a manufacturing method for coating mobile device cover substrates with a coating in which the coating is applied via a plasma-enhanced PVD process in which the cover substrates are temporarily mounted on a rotating drum as the coating is delivered, the improvement therein comprising:
chucking the cover substrates with a Van der Waals (VdW) chuck on carriers to be temporarily secured to the rotating drum, with the cover substrates being secured temporarily to the VdW chucks by VdW forces.
